(19) United States
(12) Patent Application Publication
(10) Pub. No.: US 2007/0161233 A1
(43) Pub. Date: Jul. 12, 2007

(54) Semiconductor Device and Method of Manufacturing the Same

(76) Inventor: Ka Moon Seok, Incheon-si (KR)

Correspondence Address: Jeff Lloyd;Saliwanchik, Lloyd & Saliwanchik, A Professional Association, P.O. Box 142950, Gainesville, FL, 32614-2950, US

(21) Appl. No.: 11/616,304

(22) Filed: Dec. 27, 2006

(30) Foreign Application Priority Data
Dec. 28, 2005 (KR) 10-2005-0132382

(51) Int. Cl. H01L 21/4763

(52) U.S. Cl. 438/638; 257/E21.579

(57) ABSTRACT

Provided is a semiconductor device and a method of manufacturing the semiconductor device. The semiconductor device includes a substrate, a titanium layer, a first titanium nitride layer, a second titanium nitride layer, and a via plug. The substrate includes an interlayer insulating layer formed thereon. The interlayer insulating layer can have a via hole. The titanium layer is formed within the via hole. The first titanium nitride layer is formed on the titanium layer through a reaction between the titanium layer and nitrogen gas. The second titanium nitride layer is formed on the first titanium nitride layer using a titanium nitride forming gas. The via plug is formed on the second titanium nitride layer, filling the via hole.

### RELATED APPLICATION(S)

This application claims priority under 35 U.S.C. §119(e) of Korean Patent Application No. 10-2005-0132382 filed Dec. 28, 2005, which is incorporated herein by reference in its entirety.

### FIELD OF THE INVENTION

The present invention relates to a semiconductor device and a method of manufacturing the semiconductor device.

### BACKGROUND OF THE INVENTION

Due to the high integration of modem semiconductor devices, via plugs (contact plugs) that connect metal lines in a multi-layer structure, or metal lines to gates, sources, and drains, are being increasingly miniaturized, so that the resistance of the via plugs increases, and the resistance of the metal lines also increases due to their reduction in width.

Because of the increase in the resistances of the via plugs and metal lines, a barrier metal layer becomes an indispensable component that must be included in the structure, so as to prevent different materials from mutually diffusing or chemically reacting, to ensure a stable contact interface. Such a barrier metal layer must possess characteristics including high conductivity, stable diffusion prevention, and thermal stability.

Below, a semiconductor device according to the related art will be described with reference to FIG. 1.

Referring to FIG. 1, an interlayer insulating layer 20 is formed on a substrate 10. The interlayer insulating layer 20 is patterned and etched to form a via hole.

Next, titanium (Ti) is deposited in the via hole to form a titanium layer 30, and titanium nitride is deposited on the titanium layer 30 to form a stabilizing titanium nitride layer 40. The titanium layer 30 and the titanium nitride layer 40 function as a barrier metal layer 60.

Then, the titanium nitride layer 40 is covered with a tungsten hexafluoride (WF₆) through chemical vapor deposition (CVD) and heated in a hydrogen atmosphere to deposit tungsten (W) thereto, after which the deposited tungsten is patterned and etched to form a via plug 50.

The chemical formula for forming tungsten using tungsten hexafluoride (WF₆) is as follows.
WF₆(g)+3H₂(g)−>W(s)+6HF(g)

However, the tungsten hexafluoride (WF₆) reacts with hydrogen, so that hydrogen fluoride (HF) is generated during the forming of the tungsten. This hydrogen fluoride (HF) causes a defect 90 by penetrating the titanium nitride layer 40 and diffusing into the titanium layer 30. When a defect 90 occurs at a contacting region of a gate, source, or drain, the contact resistance of the region increases.

Also, the reaction of the hydrogen fluoride (HF) with the titanium layer 30 (that acts as a metal barrier) induces the defect 90 that forms TiF₄, so that the titanium nitride layer 40 becomes elevated and unable to maintain conductivity of the barrier metal layer 60. Thus, it becomes difficult for the titanium nitride layer 40 to retain its diffusion preventing capability and thermal stability.

These problems are not limited to cases where hydrogen fluoride is generated through the use of titanium hexafluoride WF₆ as a via plug 50 or a metal line (not shown), but can also arise when a variety of materials are used for the via plug 50 or the metal line, which can cause diffusion of the barrier metal layer 60 or penetration of the barrier metal layer 60, contributing to many other types of defects.

### BRIEF SUMMARY

Accordingly, embodiments of the present invention are directed to a semiconductor device and a method for manufacturing the semiconductor device that may substantially obviate one or more problems due to limitations and disadvantages of the related art.

An object of the present invention is to provide a semiconductor device and a manufacturing method of the semiconductor device that can minimize the occurrence of defects caused by diffusion of hydrogen fluoride generated during the forming of a via plug or metal line after the process of forming the barrier metal layer, thereby lowering resistance of the barrier metal layer, and improving the reliability of the semiconductor device by improving its characteristics.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a semiconductor device, including: an interlayer insulating layer formed on a substrate; a titanium layer formed within a via hole formed in the interlayer insulating layer; a first titanium nitride layer formed on the titanium layer through a reaction between the titanium layer and nitrogen gas; a second titanium nitride layer formed on the first titanium nitride layer with a titanium nitride forming gas; and a via plug formed on the second titanium nitride layer for filling the via hole.

In another aspect of the present invention, there is provided a method of manufacturing a semiconductor substrate, including: preparing a substrate with an interlayer insulating layer formed thereon, the interlayer insulating layer having a via hole formed therein; forming a titanium layer within the via hole; forming a first titanium nitride layer on the titanium layer through a reaction between the titanium layer and nitrogen gas; forming a second titanium nitride layer using a titanium nitride forming gas on the first titanium nitride layer; and forming a via plug of a metal material on the second titanium nitride layer for filling the via hole.

In a further aspect of the present invention, there is provided a method of manufacturing a semiconductor device, including: preparing a substrate with an interlayer insulating layer formed thereon, the interlayer insulating layer having a via hole and a trench formed therein; forming a titanium layer within the via hole and the trench; forming a first titanium nitride layer on the titanium layer through a reaction between the titanium layer and nitrogen gas; forming a second titanium nitride layer on the first titanium nitride layer using a titanium nitride forming gas; and forming a via plug and a metal line on the second titanium nitride layer, for filling the via hole and the trench.

It is to be understood that both the foregoing general description and the following detailed description of the present invention are exemplary and explanatory and are intended to provide her explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

FIG. 1 is a sectional view of semiconductor device according to the related art.

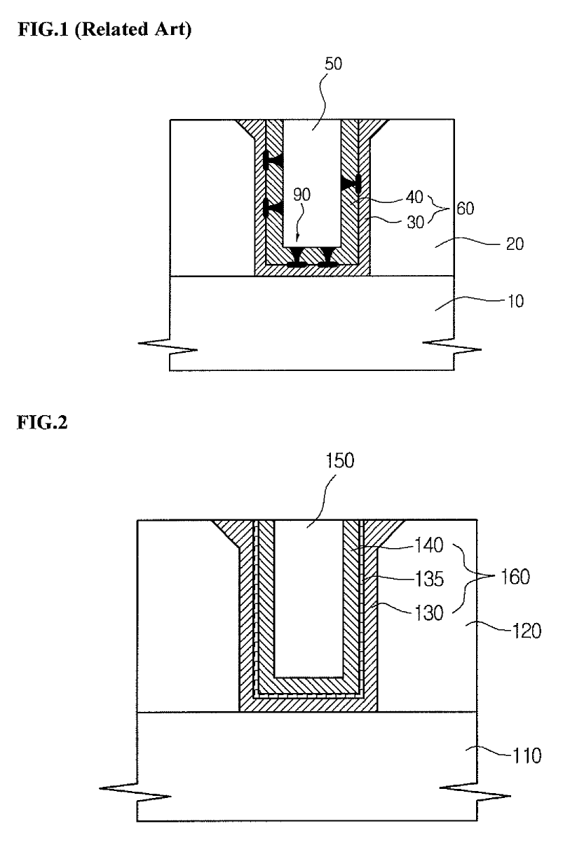

FIG. 2 is a sectional view of a semiconductor device according to an embodiment of the present invention.

FIGS. 3 through 6 are sectional views showing a manufacturing process of a semiconductor device according to an embodiment of the present invention.

FIG. 7 is a sectional view of a semiconductor device according to another embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Below, a semiconductor device and a manufacturing method thereof according to embodiments of the present invention will be described with reference to the drawings.

### First Embodiment

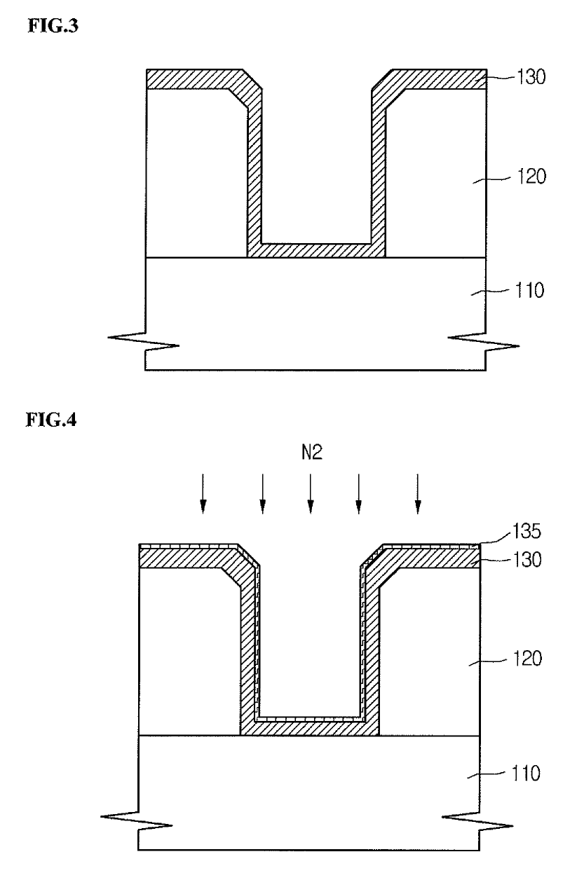

Fig. 2 is a sectional view of a semiconductor device according to a first embodiment of the present invention.

A semiconductor device according to a first embodiment of the present invention includes an interlayer insulating layer 120, including a via hole, formed on a substrate 110; a titanium layer 130 formed within the via hole; a first titanium nitride layer 135 formed on the titanium layer 130; a second titanium nitride layer 140 formed on the first titanium nitride layer 135; and a via plug 150 formed on the second titanium nitride layer 140 filling the via hole.

The titanium layer 130, the first titanium nitride layer 135, and the second titanium nitride layer 140 are collectively called a barrier metal layer 160. In an embodiment, the material of the via plug 150 may be tungsten or another metal.

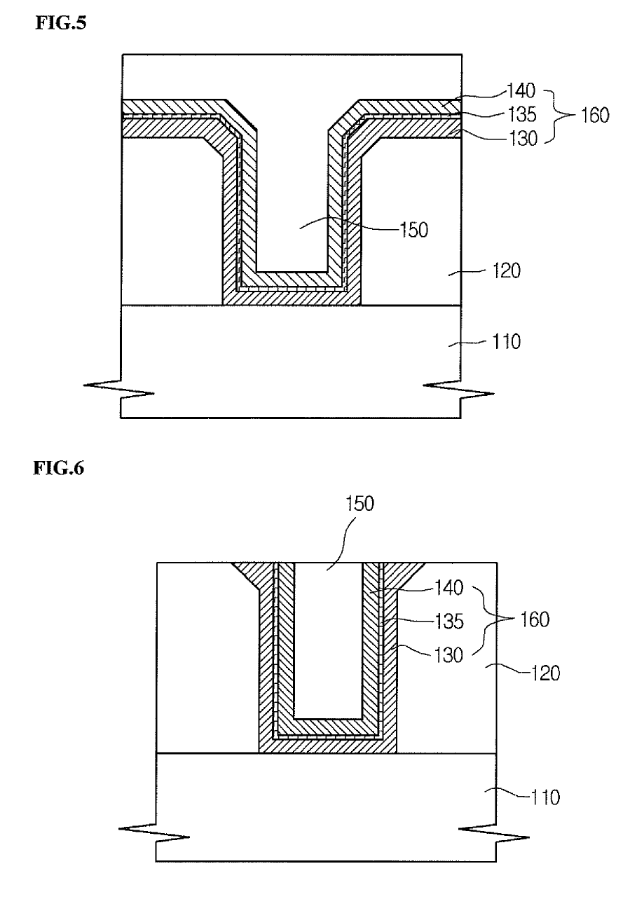

FIGS. 3 through 6 are sectional views showing a manufacturing process of a semiconductor device according to a first embodiment of the present invention.

The manufacturing process of a semiconductor substrate according to the first embodiment of the present invention can incorporate forming a via hole in an interlayer insulating layer formed on a semiconductor substrate, forming a titanium layer within the via hole, forming a first titanium nitride layer on the titanium layer through a reaction between the titanium layer and nitrogen gas, forming a second titanium nitride layer with a titanium nitride forming gas on the first titanium nitride layer, and forming a via plug of a metal material on the second titanium nitride layer, for filling the via hole.

Referring to FIG. 3, an interlayer insulating layer 120 can be formed on a substrate 110. Then a via hole can be formed in the interlayer insulating layer 120

Following the preparation of the substrate 110 with the interlayer insulating layer 120, a degassing process for removing moisture and gas from the substrate 110 and a process of cleaning the substrate 110 can be performed.

The degassing process is a process that uses a halogen lamp aligned with the substrate 110 to heat the substrate 110 and remove moisture and gas from the substrate 110.

The process of cleaning the substrate 110 can include a process of sputtering argon (Ar) plasma to clean an oxide layer on the surface of the substrate 110 or the edges at the entrance of the via hole.

Next, titanium can be thinly deposited on the interlayer insulating layer 120 including the via hole to form a titanium layer 130

Next, referring to FIG. 4, a first titanium nitride layer 135 can be thinly formed on the titanium layer 130 using nitrogen gas.

The process of forming the first titanium nitride layer 135 can involve heating the substrate 110 to a predetermined temperature, and maintaining a nitrogen gas atmosphere of 1 Torr or more for a duration of 10 or more seconds on the substrate 110 to form the first titanium nitride layer.

For example, in one embodiment, the substrate 110 may be heated to 300° C. or more. Then, the substrate 110 may be subjected to a nitrogen gas atmosphere of 1-50 Torr for 10 or more seconds to form the first titanium nitride layer 135.

When the substrate 110 is heated, the titanium layer 130 deposited on the substrate 110 and the nitrogen gas are heated, so that the titanium layer 130 and the nitrogen react to form the first titanium nitride layer 135.

The heating duration may be 10 seconds or more for maintaining the nitrogen atmosphere, depending on the thickness of the first titanium nitride layer 135. Even if the substrate 110 is subjected to this temperature for a prolonged period, there appears to be no detrimental effects thereto.

Next, referring to FIG. 5, a second titanium nitride layer 140 can be formed on the first titanium nitride layer 135, using a titanium nitride forming gas. The titanium layer 130, the first titanium layer 135, and the second titanium layer 140 can be collectively called the barrier metal layer 160.

In one embodiment, the process of forming the second titanium nitride layer 140 may include introducing a titanium nitride forming gas onto the first titanium nitride layer 135, and thermally decomposing the titanium nitride forming gas to form an amorphous titanium nitride, after which a plasma is formed with nitrogen and hydrogen gas on the titanium nitride to crystallize the titanium nitride, thus forming the second titanium nitride layer 140.

More specifically, the titanium nitride forming gas can be tetrakis dimethylamino titanium (TDMAT) that is injected into a chamber using an He Carrier. The TDMAT can be heated to 400° C. or higher to induce thermal decomposition to form an amorphous second titanium nitride layer 140.

The second titanium nitride layer 140 in an amorphous state may then be deposited through a CVD process.

Also, an adequately thick second titanium nitride layer 140 may be formed through deposition with a duration of 10-35 seconds, depending on the required thickness.

Next, to crystallize the titanium nitride in an amorphous state, hydrogen and nitrogen can be introduced and a power of 700- 800W can be applied to form the plasma and crystallize the amorphous titanium nitride. Carbon and other foreign substances residing in the titanium nitride can be removed, thereby forming a dense second titanium nitride layer 140. The duration of the plasma treating may last for 25-50 seconds in order to crystallize the amorphous titanium nitride and completely remove carbon and other foreign substances that are residing in the titanium nitride, and form a dense layer.

Subsequently, referring to FIG. 5, a via plug 150 formed of a predetermined metal material can be formed on the second titanium nitride layer 140, filling the via hole.

The forming of the via plug 150 may include filling tungsten hexafluoride (WF₆) on the second titanium nitride layer 140 through CVD, and heating the same in a hydrogen atmosphere. The metal material forming the via plug 150 may be copper, aluminum, or another metal instead of tungsten.

When the metal forming the via plug 150 is tungsten, WC1₆ may be used as a tungsten source instead of tungsten hexafluoride WF₆, and the method used of filling the tungsten may be physical vapor deposition (PVD) instead of CVD.

Here, the chemical formula for using tungsten hexafluoride to generate tungsten is:
WF₆(g)+3H₂(g)−>W(s)+6HF(g)

Here, when the processing temperature falls below 500° C. in a CVD of tungsten (CVD-W) process using hydrogen, selective deposition is possible because some materials catalyze hydrogen decomposition while others do not. At a temperature of 500° C. or more, because tungsten deposition is performed on the entire region of the substrate including the interlayer insulating layer 120 of SiO₂, a temperature of below 500° C. may be maintained for forming the via plug 150 in the via hole.

Due to the presence of the first titanium nitride layer 135, the reliability of the semiconductor substrate can be increased by inhibiting a reduction in the contact resistance of the via plug through preventing the diffusion of hydrogen fluoride (HF), which can be generated during tungsten deposition.

Next, referring to FIG. 6, metal used for the via plug 150 that is not filled in the via hole can be planarized using, for example, an etchback process to complete the formation of the via plug 150.

Then, metal lines may be formed over the via plug 150.

As described above and in accordance with embodiments of the present invention, a first titanium nitride layer 135 can be formed on the surface of a titanium layer 130, which acts as a barrier metal layer 160. In addition, the contact resistance can be lowered by minimizing the diffusion of hydrogen fluoride (HF) that can be generated during the forming of the via plug. Also, the occurrence of defects is inhibited by blocking a reaction with the titanium layer 130, thereby raising the reliability of the semiconductor device to reduce the number of product defects and increase yield.

### Second Embodiment

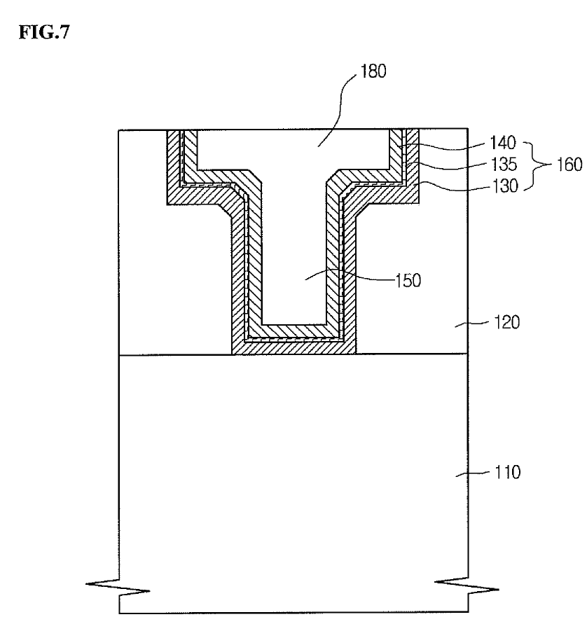

FIG. 7 is a sectional view of a semiconductor device according to a second embodiment of the present invention.

The semiconductor device manufacturing method according to the second embodiment of the present invention can incorporate forming a via hole and a trench in an interlayer insulating layer 120, forming a first titanium nitride layer 135 on the titanium layer 130 through a reaction between the titanium layer 130 and nitrogen gas, forming a second titanium nitride layer 140 with a titanium nitride forming gas on the first titanium nitride layer 135, and forming a via plug 150 and a metal line 180 on the second titanium nitride layer 140, filling the via hole and the trench.

The manufacturing method according to the second embodiment of the present invention can involve a dual damascene process to form the via hole and the trench for the metal line such that a barrier metal layer 160 can be formed on the via hole and the trench, and the via hole and the trench can be simultaneously filled to simultaneously form the via plug 150 and the metal line 180.

The forming of the via hole and the trench in the interlayer insulating layer 120 may involve first forming the trench and then the via hole in the interlayer insulating layer 120 or first forming the via hole and then the trench in the interlayer insulating layer 120.

The method of the second embodiment can be similar to that of the first embodiment of the present invention.

For example, the manufacturing process according to the second embodiment of the present invention may further include a degassing process for removing moisture and gas from the substrate and a process of cleaning the substrate 110, following the preparing of the substrate 110.

Additionally, the forming of the first titanium nitride layer 135 may include heating the substrate 110 to a predetermined temperature and maintaining the substrate 110 in a nitrogen gas atmosphere of 1-50 Torr for a duration of 10 seconds or more.

Also, the forming of the second titanium nitride layer 140 may include introducing a titanium nitride forming gas on the first titanium nitride layer 135, thermally decomposing the titanium nitride forming gas and forming an amorphous titanium nitride, forming a plasma on the titanium nitride with nitrogen and hydrogen gas, and crystallizing the titanium nitride to form the second titanium nitride layer 140.

In the second embodiment according to the present invention, a first titanium nitride layer 135 can be first formed through a high-temperature nitrogen process on the surface of the titanium layer 130 (that acts as a barrier metal layer 160) in order to minimize diffusion of hydrogen fluoride (HF) and reduce the contact resistance of the via plug 150 and the resistance of the metal line 180, thereby inhibiting the occurrence of defects from the reaction of hydrogen fluoride (HF) with the titanium layer 130.

As described above, in the semiconductor device and the manufacturing method of the semiconductor device according to embodiments of the present invention, a first titanium nitride layer can be first formed through a high-temperature nitrogen process on the surface of a titanium layer that acts as a barrier metal layer, so that the diffusion of hydrogen fluoride (HF) (that is a byproduct of the forming process of the via plug and the metal line) to the barrier metal layer, which causes defects, can be minimized and the contact resistance of the via plug and the resistance of the metal line can be reduced.

Also, because the occurrence of defects caused by the reaction between hydrogen fluoride HF (a byproduct of the forming process of the via plug and the metal line) and the barrier metal layer can be inhibited, the reliability of the semiconductor device improves. As a result, manufacturing yield can be increased.

It will be apparent to those skilled in the art that various modifications and variations can be made in the present invention. Thus, it is intended that the present invention covers the modifications and variations of this invention provided they come within the scope of the appended claims and their equivalents.

I claim:

1. A semiconductor device, comprising:
an interlayer insulating layer having a via hole formed on a substrate;
a titanium layer formed within the via hole;
a first titanium nitride layer formed on the titanium layer through a reaction between the titanium layer and nitrogen gas;
a second titanium nitride layer formed on the first titanium nitride layer by a titanium nitride forming gas; and
a via plug formed on the second titanium nitride layer, filling the via hole.

2. The semiconductor device according to claim 1, wherein the via plug is formed of tungsten.

3. A method of manufacturing a semiconductor substrate, comprising:
forming a via hole in an interlayer insulating layer formed on a substrate;
forming a titanium layer within the via hole;
forming a first titanium nitride layer on the titanium layer through a reaction between the titanium layer and nitrogen gas;
forming a second titanium nitride layer on the first titanium nitride layer using a titanium nitride forming gas; and
forming a via plug of a metal material on the second titanium nitride layer, filling the via hole.

4. The method according to claim 3, further comprising:
performing a degassing process for removing moisture and gas from the substrate; and
cleaning the substrate.

5. The method according to claim 4, wherein performing the degassing process comprises applying heat to the substrate using a halogen lamp that is uniformly aligned with the substrate.

6. The method of claim 4, wherein cleaning the substrate comprises sputtering an argon plasma onto an oxide layer on a surface of the substrate or an edge of an entrance of the via hole.

7. The method according to claim 3, wherein forming the first titanium nitride layer comprises:
heating the substrate to a predetermined temperature; and
maintaining the substrate in a nitrogen gas atmosphere for a duration of 10 seconds or more.

8. The method according to claim 3, wherein during the forming of the first titanium nitride layer, the nitrogen gas is compressed at 1-50 Torr.

9. The method according to claim 3, wherein forming the first titanium nitride layer comprises heating the substrate to heat the titanium layer and the nitrogen gas, so as to react the titanium layer with the nitrogen gas.

10. The method according to claim 3, wherein forming the second titanium nitride layer comprises:
introducing a titanium nitride forming gas on the first titanium nitride layer;
forming an amorphous titanium nitride by thermally decomposing the titanium nitride forming gas; and
crystallizing and stabilizing the amorphous titanium nitride by forming a plasma using nitrogen gas and hydrogen gas.

11. The method of claim 3, wherein forming the via plug comprises using a tungsten hexafluoride (WF₆) and hydrogen at a temperature of 500° C. or less.

12. A method of manufacturing a semiconductor device, the method comprising:
preparing a substrate with an interlayer insulating layer having a via hole and a trench formed thereon;
forming a titanium layer within the via hole and the trench;
forming a first titanium nitride layer on the titanium layer through a reaction between the titanium layer and nitrogen gas;
forming a second titanium nitride layer on the first titanium nitride layer using a titanium nitride forming gas; and
forming a via plug and a metal line on the second titanium nitride layer, filling the via hole and the trench.

13. The method according to claim 12, wherein preparing the substrate comprises:
performing a degassing process for removing moisture and gas from the substrate; and
cleaning the substrate.

14. The method according to claim 13, wherein performing the degassing process comprises applying heat to the substrate using a halogen lamp that is uniformly aligned with the substrate.

15. The method according to claim 13, wherein cleaning the substrate comprises sputtering an argon plasma onto an oxide layer on a surface of the substrate or an edge of an entrance of the via hole.

16. The method according to claim 12, wherein forming the first titanium nitride layer comprises:
heating the substrate to a predetermined temperature; and
maintaining the substrate in a nitrogen gas atmosphere of 1-50 Torr for a duration of 10 seconds or more.

17. The method according to claim 12, wherein forming the first titanium nitride layer comprises heating the substrate to heat the titanium layer and the nitrogen gas, so as to react the titanium layer with the nitrogen gas.

18. The method according to claim 12, wherein forming the second titanium nitride layer comprises:
introducing a titanium nitride forming gas on the first titanium nitride layer;
forming an amorphous titanium nitride by thermally decomposing the titanium nitride forming gas; and
crystallizing and stabilizing the amorphous titanium nitride by forming a plasma using nitrogen gas and hydrogen gas.

19. The method according to claim 12, wherein forming the via plug and the metal line comprises using a tungsten hexafluoride (WF₆), and hydrogen at a temperature of 500° C. or less.

20. The method according to claim 12, wherein forming the via plug and the metal line comprises using WC1₆, and hydrogen at a temperature of 500° C. or less.
